(19) United States
(12) Patent Application Publication
(10) Pub. No.: US 2015/0355551 A1
(43) Pub. Date: Dec. 10, 2015

(54) SYSTEMS FOR REMOVING PHOTORESISTS AND METHODS OF REMOVING PHOTORESISTS USING THE SAME

(71) Applicant: Samsung Electronics Co., Ltd., Suwon-si (KR)

(72) Inventors: Young-Ok KIM, Suwon-si (KR); Byoung-Moon YOON, Suwon-si (KR); Kyung-Hyun KIM, Seoul (KR); Yong-Sun KO, Suwon-si (KR)

(21) Appl. No.: 14/734,106

(22) Filed: Jun. 9, 2015

(30) Foreign Application Priority Data
Jun. 9, 2014 (KR) 10-2014-0069482

(51) Int. Cl. G03F 7/42

(52) U.S. Cl. CPC G03F 7/422

(57) ABSTRACT

A system for removing a photoresist includes a solution storage configured to store a preliminary photoresist removal solution, a solution activation unit configured to convert the preliminary photoresist removal solution from the solution storage into an activated photoresist removal solution, and a photoresist removal unit configured to receive the activated photoresist removal solution from the solution activation unit, and configured to load a substrate including a photoresist pattern formed thereon.

### CROSS-REFERENCE TO RELATED APPLICATION

This application claims priority under 35 USC §119 to Korean Patent Application No. 10-2014-0069482, filed on Jun. 9, 2014 in the Korean Intellectual Property Office (KIPO), the contents of which are incorporated by reference herein in their entirety.

### BACKGROUND

1. Field

Example embodiments relate to systems for removing photoresists and methods of removing photoresists using the same. Example embodiments also relate to systems for removing photoresists based on a wet etching process and methods of removing photoresists using the same.

2. Description of the Related Art

A photolithography process may be utilized for a formation of an insulation layer pattern and/or a conductive pattern included in a semiconductor device. In the photolithography process, a photoresist pattern may be formed on an object layer, and the photoresist pattern may be removed after an etching process.

A strip process and/or an ashing process may be performed to remove the photoresist pattern. As for the strip process, a strip solution may be used so that the photoresist pattern may be removed in a similar manner as that of a wet etching process. The strip solution may contain an acid ingredient (e.g., sulfuric acid, fluoric acid and/or phosphoric acid).

### SUMMARY

Example embodiments provide a system for removing a photoresist with an improved efficiency.

Example embodiments provide a method of removing a photoresist using a photoresist removal system with an improved efficiency.

According to example embodiments, a system for removing a photoresist includes a solution storage configured to store a preliminary photoresist removal solution, a solution activation unit configured to convert the preliminary photoresist removal solution from the solution storage into an activated photoresist removal solution, and a photoresist removal unit configured to receive the activated photoresist removal solution from the solution activation unit, and configured to load a substrate including a substrate including a photoresist pattern formed thereon.

In example embodiments, the solution activation unit may include a reactor configured to receive the preliminary photoresist removal solution, and at least one energy supplier configured to irradiate an activation energy onto the reactor.

In example embodiments, the at least one energy supplier may include an ultraviolet lamp.

In example embodiments, the at least one energy supplier may be a plurality of the energy suppliers arranged in parallel in the solution activation unit, and the reactor may include a plurality of activation flow paths between the plurality of energy suppliers.

In example embodiments, the at least one energy supplier may be a plurality of the energy suppliers arranged in parallel in the solution activation unit, and the reactor may include an activation flow path extending between the plurality of energy suppliers in a continuous zigzag structure.

In example embodiments, the system may further include a first flow path between the reactor and the solution storage, a second flow path between the reactor and the photoresist removal unit, a first mass flow controller in the first flow path, and a second mass flow controller in the second flow path.

In example embodiments, the system may further include an activation monitoring device coupled to the reactor for measuring a degree of activation in the activated photoresist removal solution.

In example embodiments, the second mass flow controller may be opened when a target value of the degree of activation is measured by the activation monitoring device.

In example embodiments, the photoresist removal unit may include a supporter on which the substrate is loaded, and a removal solution supplier on the supporter. The removal solution supplier may be configured to provide the activated photoresist removal solution onto the substrate.

According to example embodiments, a method of removing a photoresist may include preparing a preliminary photoresist removal solution including a peroxide, activating the preliminary photoresist removal solution to produce an activated photoresist removal solution, loading a substrate on which a photoresist pattern is formed in a process chamber, and providing the activated photoresist removal solution into the process chamber.

In example embodiments, the peroxide may consist essentially of hydrogen peroxide.

In example embodiments, the activated photoresist removal solution may include a hydroxyl radical generated from the peroxide.

In example embodiments, an acid ingredient may be excluded from the preliminary photoresist removal solution.

In example embodiments, in activating the preliminary photoresist removal solution, an ultraviolet light may be irradiated onto the preliminary photoresist removal solution.

In example embodiments, an absorbance of one of the preliminary photoresist removal solution and the activated photoresist removal solution may be measured in real-time.

According to example embodiments, a system for removing a photoresist includes a first unit configured to store a photoresist removal solution, the photoresist removal solution including a peroxide, a second unit configured to expose the photoresist removal solution, and a third unit configured to apply the exposed photoresist removal solution to a photoresist pattern.

In example embodiments, the second unit may expose the photoresist removal solution using UV irradiation.

In example embodiments, the photoresist removal solution may exclude an acid.

In example embodiments, the exposed photoresist removal solution may include a hydroxide radical generated from the peroxide.

In example embodiments, the peroxide may consist essentially of hydrogen peroxide.

### BRIEF DESCRIPTION OF THE DRAWINGS

Example embodiments will be more clearly understood from the following detailed description taken in conjunction with the accompanying drawings. FIGS. 1 to 17 represent non-limiting, example embodiments as described herein.

FIG. 1 illustrates a schematic construction of a system for removing a photoresist in accordance with example embodiments;

FIG. 2 illustrates a schematic construction of a system for removing a photoresist in accordance with example embodiments;

FIG. 3 illustrates a schematic construction of a system for removing a photoresist in accordance with example embodiments;

FIG. 4 illustrates a schematic construction of a system for removing a photoresist in accordance with example embodiments;

FIG. 5 is a flow chart illustrating a method of removing a photoresist in accordance with example embodiments; and

FIGS. 6 to 17 are cross-sectional views and top plan views illustrating a method of manufacturing a semiconductor device in accordance with example embodiments.

### DETAILED DESCRIPTION

Various example embodiments will be described more fully hereinafter with reference to the accompanying drawings, in which some example embodiments are shown. The present inventive concepts may, however, be embodied in many different forms and should not be construed as limited to the example embodiments set forth herein. Rather, these example embodiments are provided so that this description will be thorough and complete, and will fully convey the scope of the present inventive concepts to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, fourth etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concepts.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concepts. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concepts.

Unless otherwise defined, all terms (including technical and scientific terms) used herein have the same meaning as commonly understood by one of ordinary skill in the art to which the inventive concepts belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments of the present inventive concepts are described in detail with reference to the accompanying figures.

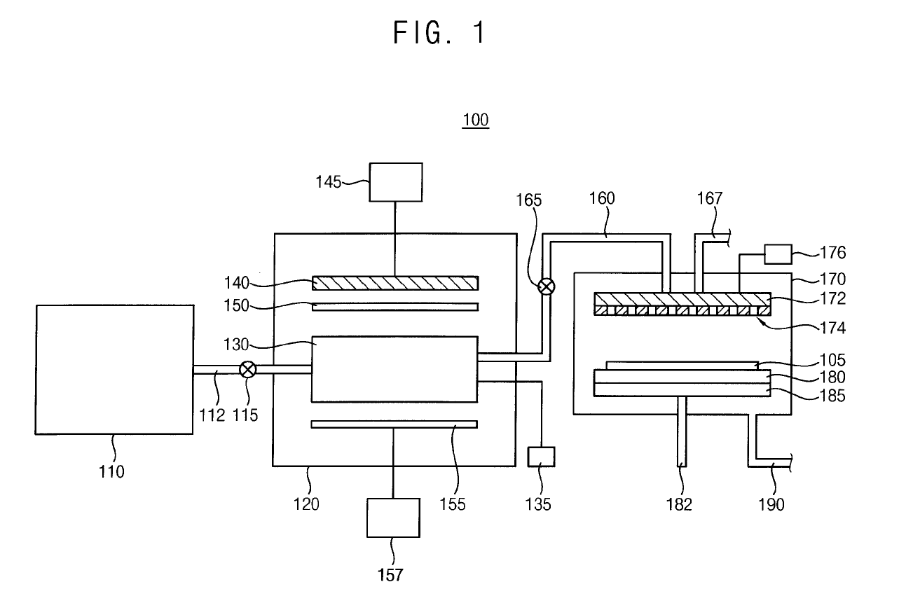

FIG. 1 illustrates a schematic construction of a system for removing a photoresist in accordance with example embodiments.

Referring to FIG. 1, a system for removing a photoresist 100 (hereinafter, abbreviated as a system) may include a solution storage 110, a solution activation unit 120 and a photoresist removal unit 170.

A preliminary photoresist removal solution may be stored in the solution storage 110, and may be provided into the solution activation unit 120.

In example embodiments, the preliminary photoresist removal solution may include a peroxide (e.g., hydrogen peroxide (H₂O₂)). Further, the preliminary photoresist removal solution may not include an acid ingredient (e.g., sulfuric acid, phosphoric acid, fluoric acid, and/or nitric acid). In example embodiments, the preliminary photoresist removal solution may include an additional ingredient (e.g., a radical initiator).

The preliminary photoresist removal solution may be transferred from the solution storage 110 to the solution activation unit 120 through a first flow path 112. A first mass flow controller (MFC) 115 may be disposed in the middle of the first flow path 112 to control a flow rate of the preliminary photoresist removal solution which may be provided into the solution activation unit 120.

A reactivity or an activity of the preliminary photoresist removal solution may be increased in the solution activation unit 120. The solution activation unit 120 may include a reactor 130 and an energy supplier 140. An activation reaction of the preliminary removal solution may occur in the reactor 130. In example embodiments, an ultraviolet (UV) lamp may be used as the energy supplier 140.

The preliminary photoresist removal solution from the solution storage 110 may be contained in the reactor 130. For example, a UV irradiation may be performed on the preliminary photoresist removal solution through the energy supplier 140 so that the preliminary photoresist removal solution may be transformed into an activated photoresist removal solution.

In example embodiments, the activated photoresist removal solution may include an active species created from the peroxide of the preliminary photoresist removal solution. The peroxide may be decomposed by the UV irradiation to create the active species. For example, the active species may include a hydroxyl radical (.OH). The activated photoresist removal solution may substantially serve as a photoresist strip solution.

A wavelength controller 145 may be coupled to the energy supplier 140 so that a wavelength of a UV light from the energy supplier 140 may be adjusted. In example embodiments, the UV light of a wavelength ranging from about 100 nm to about 400 nm may be irradiated from the energy supplier 140. If the wavelength is less than about 100 nm, the reactor 130 may be damaged, and the preliminary photoresist removal solution may be over-reacted to generate undesired chemical species other than the hydroxyl radical. If the wavelength exceeds about 400 nm, the activation or the radicalization of the preliminary photoresist removal solution may not be substantially initiated. In example embodiments, the wavelength of the UV light may range from about 200 nm to about 300 nm.

In example embodiments, a transparent member 150 may be interposed between the energy supplier 140 and the reactor 130. An intensity of the UV light supplied to the reactor 130 may be controlled by the transparent member 150. For example, the transparent member 150 may be formed of quartz. As illustrated in FIG. 1, the transparent member 150 may have a plate shape or a bar shape between the energy supplier 140 and the reactor 130. In example embodiments, the transparent member 150 may surround the energy supplier 140.

The solution activation unit 120 may further include a first temperature controller 157. A temperature in the reactor 130 or a temperature of the solution stored in the reactor 130 may be increased by the first temperature controller 157.

For example, a reaction temperature or an activation temperature of the preliminary photoresist removal solution may be adjusted in a range of from about 50° C. to about 150° C. by the first temperature controller 157. If the temperature is less than about 50° C., the activation or the radicalization of the preliminary photoresist removal solution may not be substantially initiated. If the temperature exceeds about 150° C., the preliminary photoresist removal solution may be over-reacted to generate the undesired chemical species other than the hydroxyl radical. In example embodiments, the temperature may be adjusted in a range of from about 90° C. to about 150° C.

In example embodiments, an infrared lamp 155 may be further disposed to adjust the temperature of the solution stored in the reactor 130. In example embodiments, a wavelength of the infrared lamp 155 may be controlled by the first temperature controller 157.

As illustrated in FIG. 1, for example, the energy supplier 140 may be disposed on the reactor 130 to activate the preliminary photoresist removal solution, and the infrared lamp 155 may be disposed under the reactor 130 to control a temperature for an activating reaction.

However, an arrangement and/or a construction of the energy supplier 140 and the infrared lamp 155 may be modified properly for improving an efficiency of the activating reaction. For example, the energy supplier 140 may be disposed on and/or under the reactor 130, and the infrared lamp 155 may surround a lateral portion of the reactor 130. Alternatively, the energy supplier 140 may surround the lateral portion of the reactor 130, and the infrared lamp 130 may be disposed on and/or under the reactor 130.

The activated photoresist removal solution created in the reactor 130 may be provided into the photoresist removal unit 170 through a second flow path 160. A second MFC 165 may be disposed in the middle of the second flow path 160 to control a flow rate of the activated photoresist removal solution provided into the photoresist removal unit 170.

In example embodiments, the solution activation unit 120 may further include an activation monitoring device 135 coupled to the reactor 130. The activation monitoring device 135 may be configured to measure or monitor the degree of the activation or the radicalization from the preliminary photoresist removal solution to the activated photoresist removal solution.

For example, when the activation monitoring device 135 determines that hydrogen peroxide contained in the preliminary photoresist removal solution is substantially and entirely converted into the hydroxyl radical, a predetermined or given signal may be transferred to the second MFC 165. Accordingly, the second MFC 165 may be opened so that the activated photoresist removal solution may be introduced into the photoresist removal unit 170 through the second flow path 160.

In example embodiments, the activation monitoring device 135 may include an absorbance measuring device. For example, an absorbance measured when hydrogen peroxide is substantially converted into the hydroxyl radical may be set as a target absorbance. When an absorbance of the solution in the reactor 130 reaches the target absorbance, an opening signal may be transferred to the second MFC 165 so that the activated photoresist removal solution may be supplied through the second flow path 160.

In example embodiments, an absorbance I₀ of the preliminary photoresist removal solution containing hydrogen peroxide may be measured before the activation or the radicalization is progressed. An absorbance I₁ of the activated photoresist removal solution may be measured in real-time, and an absorbance ratio I₁/I₀ may be calculated. When the absorbance ratio reaches a predetermined or given target value, the opening signal may be transferred to the second MFC 165 to provide the activated photoresist removal solution through the second flow path 160.

The photoresist removal unit 170 may substantially serve as a photoresist strip device. In example embodiments, the photoresist removal unit 170 may include a removal solution supplier 172 for injecting the activated photoresist removal solution provided through the second flow path 160, and a supporter 180 on which a substrate 105 including a photoresist pattern formed thereon may be loaded.

The removal solution supplier 172 may be disposed over the substrate 105 to substantially overlap a top surface of the substrate 105. The removal solution supplier 172 may include a plurality of injection holes 174 regularly arranged for a uniform injection of the activated photoresist removal solution. The removal solution supplier 172 may have a space for temporarily storing the activated photoresist removal solution.

A second temperature controller 176 may be coupled to the removal solution supplier 172 so that a temperature of the activated photoresist removal solution may be maintained while providing the solution on the substrate 105. The removal solution supplier 172 may include a metal, and thus an efficiency of a thermal conductivity for the activated photoresist removal solution may be improved.

The substrate 105 may be a semiconductor substrate including, e.g., single crystalline silicon or single crystalline germanium. A predetermined or given pattern structure including an insulative pattern or a conductive pattern may be formed on the substrate 105. The photoresist pattern serving as an etching mask may remain on the pattern structure.

The substrate 105 may be loaded on the supporter 180 located at a lower space of the photoresist removal unit 170. In example embodiments, a plurality of the substrates 105 may be loaded on the supporter 180. For example, a susceptor including a plurality of slots may be placed on the supporter 180, and the substrate 105 may be loaded on each slot.

The supporter 180 may be rotatably coupled to a chuck 182. The chuck 182 may extend through the photoresist removal unit 170. The supporter 180 may be rotated by the chuck 182 while injecting the activated photoresist removal solution. Accordingly, a photoresist removal process may be performed uniformly and simultaneously on the plurality of the substrates 105.

In example embodiments, a third temperature controller 185 may be provided. A temperature of the substrate 105 may be increased by the third temperature controller 185. The third temperature controller 185 may be in contact with a lower face of the supporter 180, and the temperature of the substrate 105 may be increased through the supporter 180. The supporter 180 and the third temperature controller 185 may include a metal for an improved efficiency of a heat transfer.

In example embodiments, the chuck 182 may also serve as a temperature controller while rotating the supporter 180. In example embodiments, the chuck 182 may include a metal having an improved efficiency of a heat transfer so that a heat may be transferred from the chuck 182 to the supporter 180.

A drain 190 may be disposed at a lower portion of the photoresist removal unit 170. The activated photoresist removal solution remaining after a reaction with the substrate 105 may be discharged out of the photoresist removal unit 170.

In example embodiments, the photoresist removal unit 170 may further include a third flow path 167 through which a cleaning solution may be provided after a process for removing the photoresist pattern on the substrate 105. The cleaning solution may include, e.g., a pure water or a deionized water.

As illustrated in FIG. 1, the third flow path 167 may be coupled to the removal solution supplier 172. In example embodiments, the cleaning solution may be injected through the removal solution supplier 172 after a completion of the process for removing the photoresist pattern by providing the activated photoresist removal solution through the removal solution supplier 172. Thus, a cleaning solution may be applied to the substrate 105.

Alternatively, the third flow path 167 may be separated from the removal solution supplier 172 to individually provide the cleaning solution on the substrate 105.

In example embodiments, the photoresist removal unit 170 may be combined with a photoresist ashing device. A plasma or a UV light may be generated by the photoresist ashing device to remove a photoresist. In example embodiments, the photoresist pattern formed on the substrate 105 may be preliminarily removed using the photoresist ashing device, and then the substrate 105 may be transferred into the photoresist removal unit 170. Accordingly, a photoresist strip process may be performed using the activated photoresist removal solution.

A transfer chamber may be interposed between the photoresist removal unit 170 and the photoresist ashing device for transferring the substrate 105.

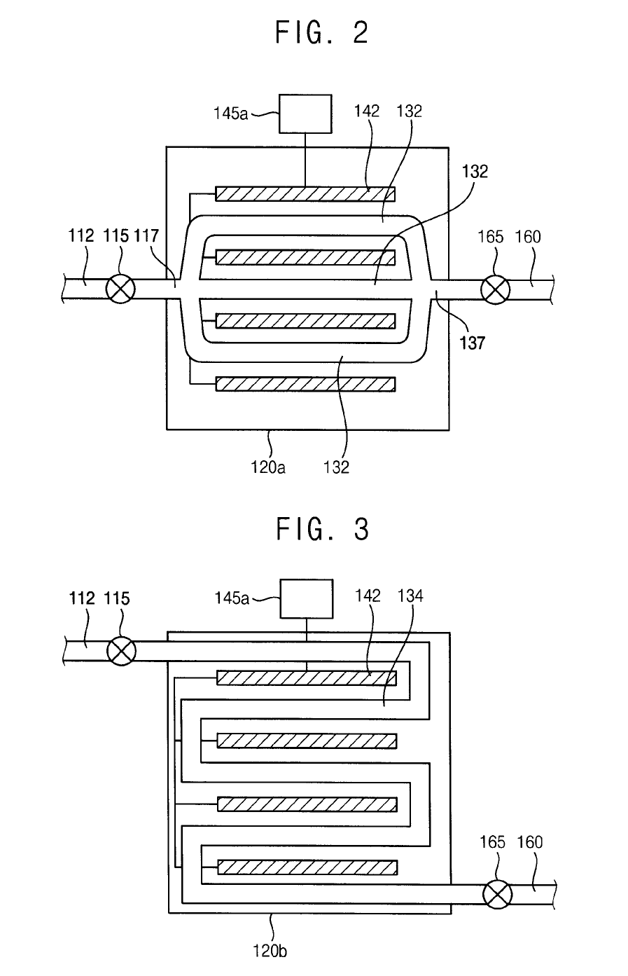

FIG. 2 illustrates a schematic construction of a system for removing a photoresist in accordance with example embodiments. For example, FIG. 2 illustrates a modified example of the solution activation unit in the system 100 of FIG. 1.

Referring to FIG. 2, a plurality of energy suppliers 142 may be placed in a solution activation unit 120a. For example, the plurality of the energy suppliers 142 may be arranged parallelly, and a wavelength controller 145a may form a parallel connection with the plurality of the energy suppliers 142.

The reactor 130 illustrated with reference to FIG. 1 may include a plurality of activation flow paths 132 as illustrated in FIG. 2.

For example, the first flow path 112 may enter the solution activation unit 120a and may be diverged into the plurality of the activation flow paths 132 from an extension portion 117. Each of the activation flow paths 132 may be interposed between the energy suppliers 142. In example embodiments, each of the activation flow paths 132 may be interposed between a pair of the energy suppliers 142 as illustrated in FIG. 2.

Accordingly, the preliminary photoresist removal solution in one of the activation flow paths 132 may be activated by, e.g., a UV irradiation from two of the energy suppliers 142. Thus, an amount of an energy irradiation per a unit volume of the preliminary photoresist removal solution may be increased so that an activated photoresist removal solution that may be sufficiently radicalized may be produced in a relatively short time.

As described above, when the activation monitoring device determines that a sufficient activation occurs, the activated photoresist removal solution may be provided into the photoresist removal unit 170 through the second flow path 160 via a converging portion 137.

FIG. 3 illustrates a schematic construction of a system for removing a photoresist in accordance with example embodiments. For example, FIG. 3 illustrates a modified example of the solution activation unit in the system 100 of FIG. 1.

Referring to FIG. 3, a plurality of the energy suppliers 142 may be placed in a solution activation unit 120b as illustrated in FIG. 2. For example, the plurality of the energy suppliers 142 may be arranged parallelly, and the wavelength controller 145a may form a parallel connection with the plurality of the energy suppliers 142.

The reactor 130 illustrated with reference to FIG. 1 may include an activation flow paths 134 as illustrated in FIG. 3. The activation flow path 134 may be placed in the solution activation unit 120b, and may have a zigzag shape continuously extending from the first flow path 112.

In example embodiments, the activation flow path 134 may continuously extend in spaces between the energy suppliers 142 arranged parallelly to each other. Accordingly, the preliminary photoresist removal solution passing through the activation flow path 134 may be irradiated continuously by, e.g., a UV light from the plurality of the energy suppliers 142. Thus, a peroxide (e.g., hydrogen peroxide) contained in the preliminary photoresist removal solution may be substantially and completely converted into a hydroxyl radical to produce an activated photoresist removal solution.

As described above, an activation monitoring device may be coupled to the activation flow path 134. A degree of activation may be measured in real-time by the activation monitoring device, and a flow rate in the activation flow path 134 may be properly adjusted using the first and second MFCs 115 and 165. When the activation monitoring device determines that a sufficient activation or a sufficient radicalization occurs, the second MFC 165 may be fully opened to provide the activated photoresist removal solution into the photoresist removal unit 170.

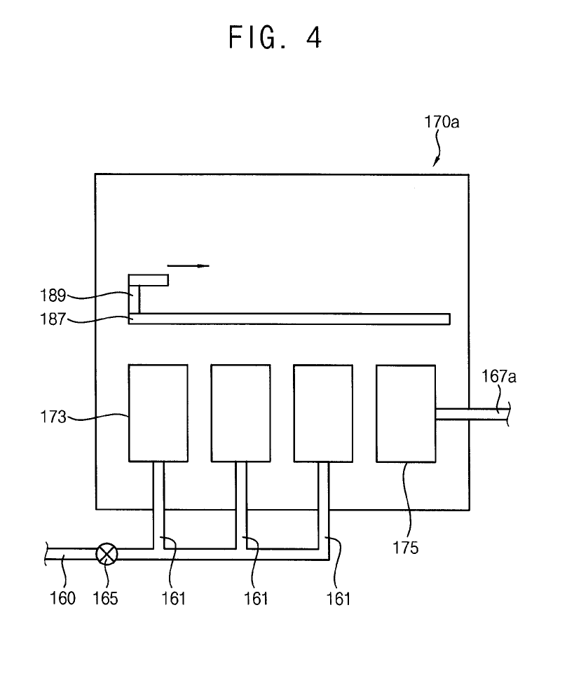

FIG. 4 illustrates a schematic construction of a system for removing a photoresist in accordance with example embodiments. For example, FIG. 4 illustrates a modified example of the photoresist removal unit in the system 100 of FIG. 1.

Referring to FIG. 4, a photoresist pattern formed on a substrate may be removed by being immersed into an activated photoresist removal solution in a photoresist removal unit 170a.

In example embodiments, at least one removal solution bath 173 may be placed on the photoresist removal unit 170a. For example, a plurality of the removal solution baths 173 may be arranged, and the plurality of the removal solution baths 173 may be connected parallelly to each other by supply flow paths 161 diverged from the second flow path 160. Accordingly, the activated photoresist removal solution may be stored in each of the removal solution baths 173.

The photoresist removal unit 170a may include a substrate loading device 187. For example, the substrate loading device 187 may be coupled to a transfer robot 189 for moving and immersing a substrate into the removal solution bath 173. The transfer robot 189 may be moved horizontally on the substrate loading device 187, provide the substrate into the removal solution bath 173, and carry the substrate after a completion of a photoresist removal from the removal solution bath 173 to a cleaning solution bath 175.

The cleaning solution bath 175 may be coupled to a third flow path 167a and contain a cleaning solution (e.g., a pure water or a deionized water).

In example embodiments, a single substrate may be immersed into each of the removal solution baths 173. Thus, a single wafer-type photoresist strip process may be performed. A drain may be coupled to each of the removal solution bath 173 and the cleaning solution bath 175 so that solutions after performing strip and cleaning processes may be discharged out of the photoresist removal unit 170a.

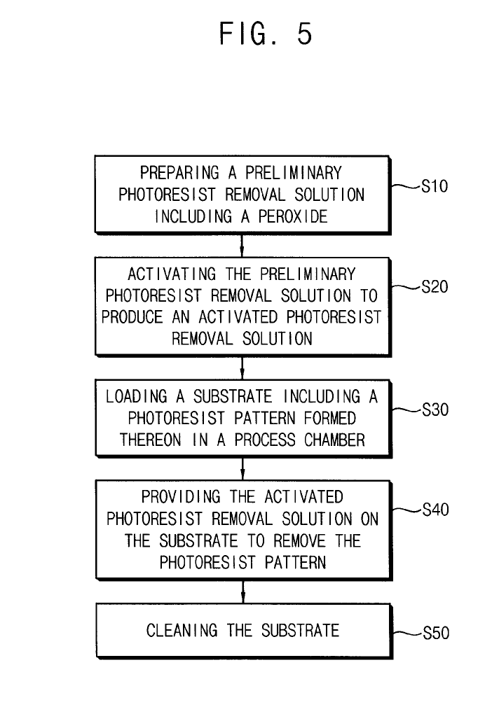

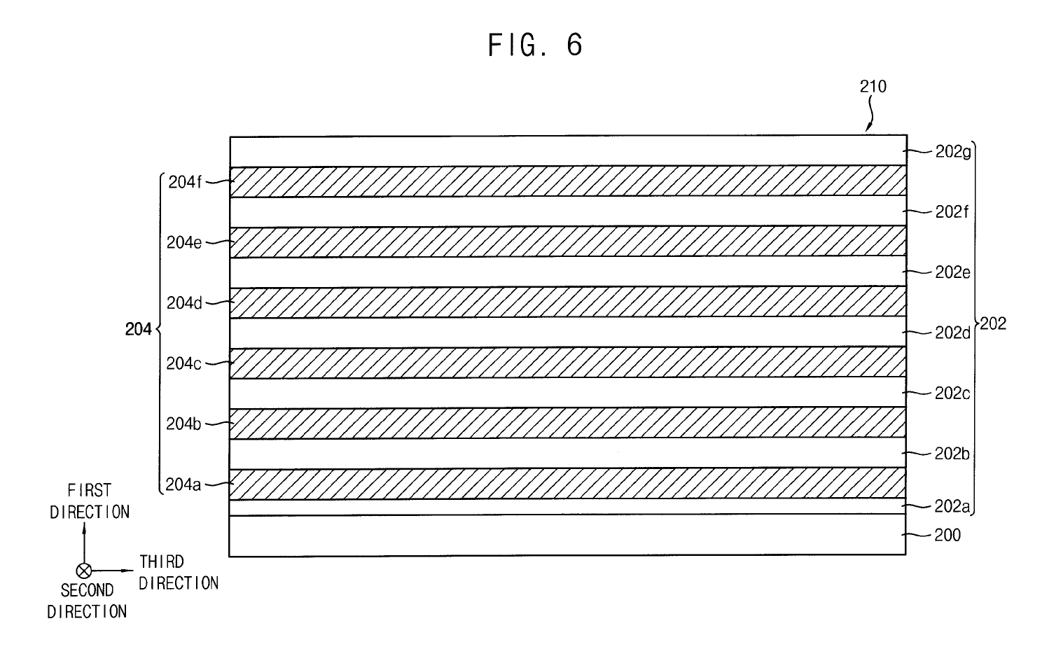

FIG. 5 is a flow chart illustrating a method of removing a photoresist in accordance with example embodiments. For example, FIG. 5 illustrates a method of removing a photoresist using the systems illustrated with reference to FIGS. 1 to 4.

Referring to FIG. 5, in operation of S10, a preliminary photoresist removal solution including a peroxide may be prepared.

Examples of the peroxide may include an inorganic peroxide, e.g., a peroxide of an alkali metal, for example, potassium persulfate, or an organic peroxide, e.g., an alkyl peroxide, a benzoyl peroxide, an acetyl peroxide or a benzyl peroxide.

In example embodiments, the peroxide contained in the preliminary photoresist removal solution may consist essentially of hydrogen peroxide. In example embodiments, the above mentioned inorganic and organic peroxides may be excluded from the preliminary photoresist removal solution. If the peroxide of the preliminary photoresist removal solution substantially consists of hydrogen peroxide, a generation ratio of a hydroxyl radical may be increased by an activation process described below. Further, a generation ratio of other active species (e.g., an oxygen radical or an ozone radical) may be decreased.

In example embodiments, the preliminary photoresist removal solution may further include an additional ingredient (e.g., a radical initiator). A radicalization of the peroxide may be facilitated by the radical initiator in the activation process. For example, an azo compound-based initiator may be used as the radical initiator.

In example embodiments, the preliminary photoresist removal solution may include a solvent (e.g., water or an alcohol-based solvent). The alcohol-based solvent may include, e.g., ethanol, methanol, isopropanol or ethylene glycol.

In example embodiments, the preliminary photoresist solution may consist essentially of the solvent and hydrogen peroxide. In example embodiments, the above mentioned inorganic and organic peroxides, and the additional ingredient (e.g., the radical initiator) may be excluded from the preliminary photoresist removal solution.

In example embodiments, the preliminary photoresist solution may not include an acid ingredient (e.g., sulfuric acid, phosphoric acid, fluoric acid and/or nitric acid). Accordingly, an environmental issue (e.g., a generation of wastewater) may be avoided. Further, insulative and/or conductive patterns other than a photoresist pattern may not be damaged by a photoresist removal solution.

In example embodiments, the preliminary photoresist removal solution may be stored in the solution storage 110 of the system 100 illustrated with reference to FIGS. 1 to 4.

In operation S20, the preliminary photoresist removal solution may be activated to produce an activated photoresist removal solution.

In example embodiments, an energy may be irradiated on the preliminary photoresist removal solution containing the peroxide so that the peroxide may be converted into an active species. Accordingly, the preliminary photoresist removal solution may be transformed into the activated photoresist removal solution.

The active species may include a hydroxyl radical. In example embodiments, the active species may consist essentially of the hydroxyl radical. In example embodiments, other active materials (e.g., an oxygen radical, an ozone radical or ozone) may be excluded from the active species. Thus, an environmental pollution by the active material that may be also harmful to humans may be reduced. Additionally, insulative and/or conductive patterns other than a photoresist material may be prevented or inhibited from being damaged by the active material.

In example embodiments, a UV light may be utilized as the energy for converting the peroxide into the active species. For example, the UV light may be irradiated on the preliminary photoresist removal solution from a UV lamp. For example, the UV light having a wavelength of from about 100 nm to about 400 nm may be irradiated from the UV lamp. In example embodiments, the UV light having a wavelength of from about 200 nm to about 300 nm may be irradiated.

In example embodiments, the preliminary photoresist removal solution stored in the solution storage 110 of the system 100 may be provided into the reactor 130 of the solution activation unit 120 through the first flow path 112. The UV light may be irradiated into the reactor 130 by the energy supplier 140 disposed in the solution activation unit 120 so that the peroxide contained in the preliminary photoresist removal solution may be activated. The activation may include a radicalization of the peroxide, and thus the peroxide may be converted into the hydroxyl radical to produce the activated photoresist removal solution.

A temperature in the reactor 130 may be adjusted by the first temperature controller 157 and/or the infrared lamp 155 to facilitate the activation. A temperature of the preliminary photoresist removal solution may be adjusted during the activation in a range of from about 50° C. to about 150° C. In example embodiments, the temperature may be adjusted in a range of about 90° C. to about 150° C.

A flow rate of the preliminary photoresist removal solution into the reactor 130 may be controlled by the first MFC 115 disposed in the middle of the first flow path 112 so that the peroxide in the preliminary photoresist removal solution may be entirely converted into the hydroxyl radical.

For example, after a predetermined or given amount of the preliminary photoresist removal solution (hereinafter, referred to as “one batch”) is provided into the reactor 130, the first flow path 112 may be closed. An absorbance of the preliminary photoresist removal solution during a UV irradiation may be measured in real-time so that a degree of radicalization of the peroxide may be determined based on a measurement of the absorbance. When the radicalization is fully progressed, the second flow path 160 may be opened by the second flow path 165 so that the activated photoresist removal solution may be introduced into the photoresist removal unit 170. Further, the first flow path 112 may be opened, and then another batch of the preliminary photoresist removal solution may be provided into the reactor 130. By repeating the above process, the activated photoresist removal solution that may be sufficiently activated may be continuously provided into the photoresist removal unit 170.

In example embodiments, the solution activation units illustrated in FIGS. 2 and 3 may be utilized for the activation or the radicalization. For example, the preliminary photoresist removal solution may be provided through spaces between energy suppliers parallelly arranged to each other, so that an area or a volume to which the energy is irradiated may be increased. Thus, the degree of activation or radicalization may be improved in the activated photoresist removal solution.

In operation S30, a substrate including a photoresist pattern formed thereon may be loaded in a process chamber. In operation S40, the activated photoresist removal solution may be introduced on the substrate to remove the photoresist pattern.

The process chamber may be a chamber for a photoresist strip process, and the activated photoresist removal solution may serve as a photoresist strip solution.

For example, the substrate may be prepared from a semiconductor wafer including a semiconductor material (e.g., single crystalline silicon or single crystalline germanium). A pattern structure including an insulative pattern and/or a conductive pattern may be formed on the substrate by a photolithography process. The photoresist pattern serving as an etching mask may be formed on the pattern structure. Impurities may be doped with the photoresist pattern so that a loss or a damage of the photoresist pattern may be reduced while performing the photolithography process.

For example, a photosensitive material (e.g., a novolac resin) may be used to form a photoresist layer on an object layer. Exposure and developing processes may be performed to remove a predetermined or given region of the photoresist layer. A remaining portion of the photoresist layer may be defined as the photoresist pattern. The object layer may be patterned using the photoresist pattern as the etching mask to form the pattern structure.

As illustrated with reference to FIG. 1, a plurality of the substrates may be loaded on the supporter 180 in the photoresist removal unit 170. While rotating the supporter 180, the activated photoresist removal solution may be provided uniformly on the plurality of the substrates.

In example embodiments, the supporter 180 may have a conveyer structure capable of moving horizontally. In example embodiments, while moving the supporter 180 horizontally, the activated photoresist removal solution may be provided on the plurality of the substrates.

The activated photoresist removal solution may be provided on the substrate by an injection method. Alternatively, the activated photoresist removal solution may be provided on the substrate by an immersion method. In example embodiments, the photoresist removal unit may include at least one removal solution bath as illustrated in FIG. 4, and at least one substrate may be immersed into the removal solution bath so that the photoresist pattern may be removed.

When the activated photoresist removal solution contacts the photoresist pattern, the active species including the hydroxyl radical may be reacted with carbon-based ingredients of the photoresist pattern to oxidize the photoresist pattern. For example, the hydroxyl radical may attack a hydrocarbon chain (e.g., an alkyl group or an olefin group) contained in the photoresist pattern so that the hydrocarbon chain may be oxidized into an intermediate (e.g., an alcohol group, a ketone group, and/or an aldehyde group). The intermediate may be further oxidized into a carboxyl group to be solubilized in the activated photoresist removal solution. Accordingly, the photoresist pattern formed on the substrate may be removed.

In operation of S50, the substrate from which the photoresist pattern is removed may be cleaned.

For example, a cleaning solution including a pure water or a deionized water may be provided on the substrate exposed to the activated photoresist removal solution for a predetermined or given time so that the activated photoresist removal solution or a photoresist residue remaining on the substrate may be cleaned or washed.

In example embodiments, the cleaning process may be performed in situ in the same process chamber as that for the process of removing the photoresist pattern by the activated photoresist removal solution. In example embodiments, as illustrated with reference to FIG. 1, the third flow path 167 for providing the cleaning solution may be integral with the removal solution supplier 172, or may be individually provided in the photoresist removal unit 170.

In example embodiments, the method for removing a photoresist in accordance with example embodiments may be performed in a combination with a photoresist ashing process. For example, the substrate may be loaded on an ashing process chamber, and the photoresist pattern may be preliminarily removed by a plasma or a light irradiation. The substrate may be transferred from the ashing process chamber to the photoresist removal unit 170 of the system 100 illustrated in FIG. 1. Accordingly, the photoresist strip process described above may be performed.

According to example embodiments described above, the preliminary photoresist removal solution including the peroxide may be sufficiently or completely activated through an energy irradiation prior to being provided on the substrate to be converted into the activated photoresist removal solution. The activated photoresist removal solution may be provided on the substrate including the photoresist pattern so that the photoresist pattern may be selectively removed in a short time.

In a comparative example, a strip solution including a peroxide may be provided on a substrate while simultaneously irradiating an energy. However, in example embodiments, the strip solution may be provided on the substrate before a sufficient activation is progressed. Thus, a time for stripping a photoresist may be increased. Accordingly, insulative and/or conductive patterns may be damaged, and the substrate may be also damaged by the strip solution.

Further, the strip solution that may not be activated or may not be fully activated may contact a photoresist pattern so that an amount of a photoresist residue remained on the substrate may be increased. Furthermore, the conductive pattern including, e.g., polysilicon or a metal may be damaged by a portion of the peroxide or a hydroxyl ion that fails to be converted into a hydroxyl radical.

Additionally, a UV light may be directly irradiated on the substrate to cause damages or deformations of the substrate and structures thereon.

However, according to example embodiments, the preliminary photoresist removal solution may be pre-activated by the energy irradiation, and then provided on the substrate. Therefore, the photoresist strip process may be performed in a reduced time while preventing or inhibiting damage to the substrate and the structures thereon.

In example embodiments, the preliminary photoresist removal solution and the activated photoresist removal solution may not include an acid ingredient. Accordingly, the insulative and the conductive pattern may be prevented or inhibited from being damaged by the acid ingredient.

For example, if fluoric acid is contained in the preliminary photoresist removal solution and the activated photoresist removal solution, the insulative pattern including silicon oxide may be damaged. If phosphoric acid, sulfuric acid and/or nitric acid are contained in the preliminary photoresist removal solution and the activated photoresist removal solution, the insulative pattern including silicon nitride may be damaged.

However, according to example embodiments, the acid ingredient may be excluded from the preliminary photoresist removal solution and the activated photoresist removal solution. Thus, a selective strip process for a photoresist material may be realized, and an environmental pollution caused by the acid ingredient may be avoided.

In example embodiments, hydrogen peroxide may be exclusively used as the peroxide. Accordingly, the peroxide may be uniformly and substantially converted into the hydroxyl radical.

When the peroxide includes inorganic or organic peroxides other than hydrogen peroxide, various active species including an oxygen radical, an ozone radical, ozone, a hydroxide ion may be generated due to different bonding forces of the peroxides. These active species may be harmful to humans, and may deteriorate a uniformity of a photoresist removal rate. Specifically, the ozone radical may have an excessive activity to cause damages of other structures.

However, hydrogen peroxide may be only used for the preliminary photoresist solution, a photoresist strip solution using the hydroxyl radical, which may be non-toxic to humans and may have a uniform removal rate may be realized.

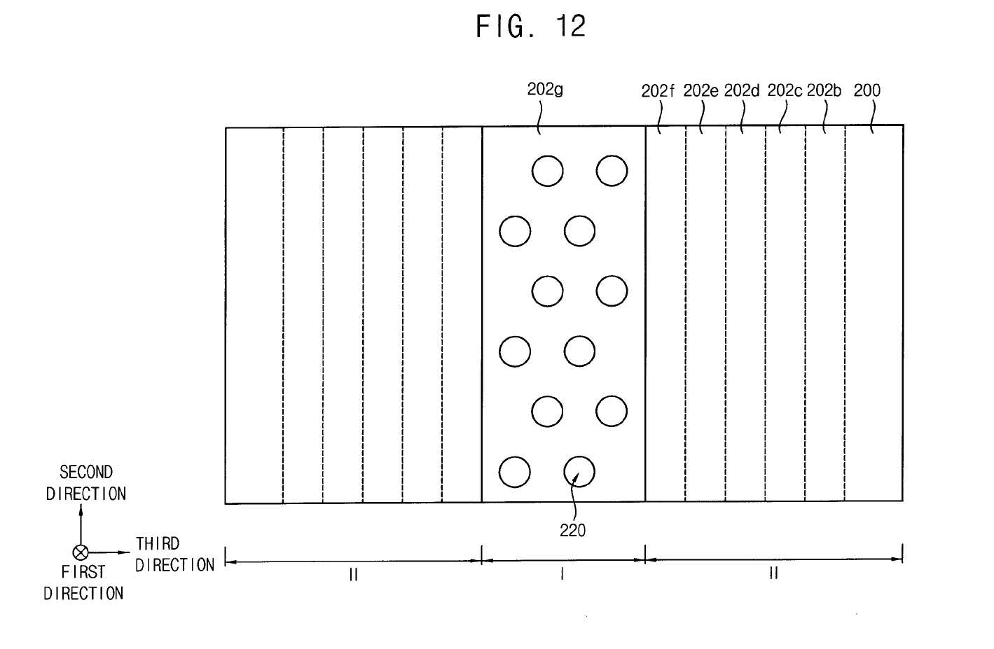

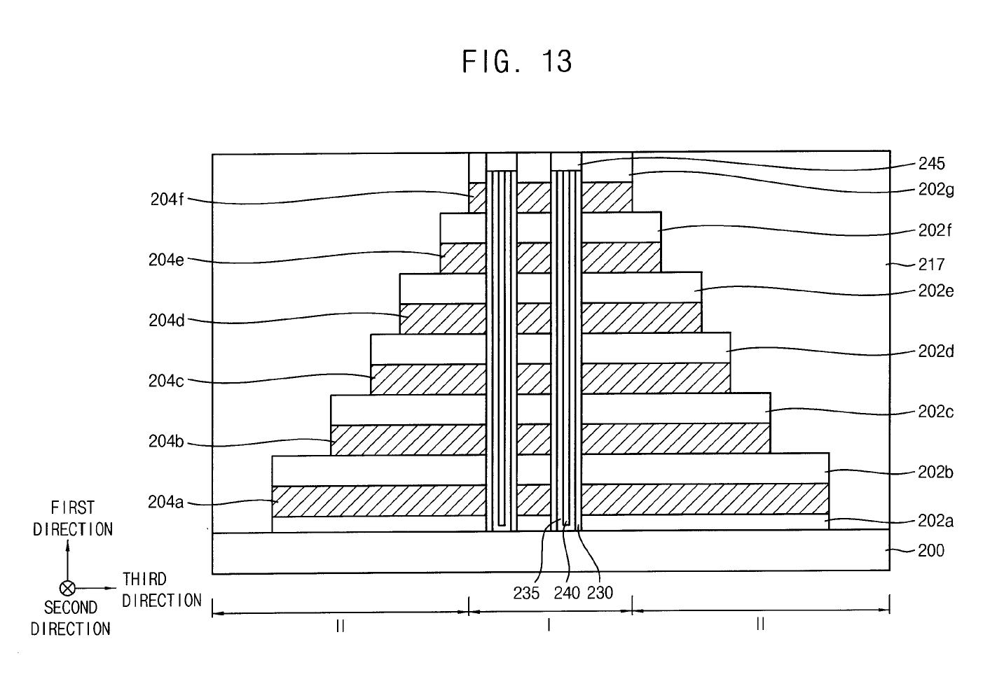

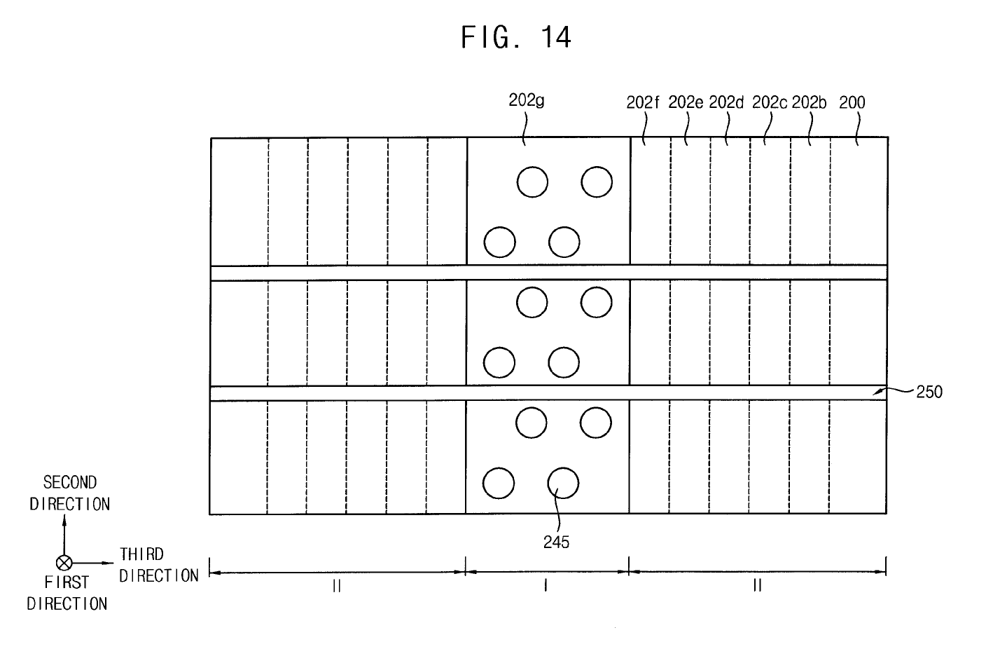

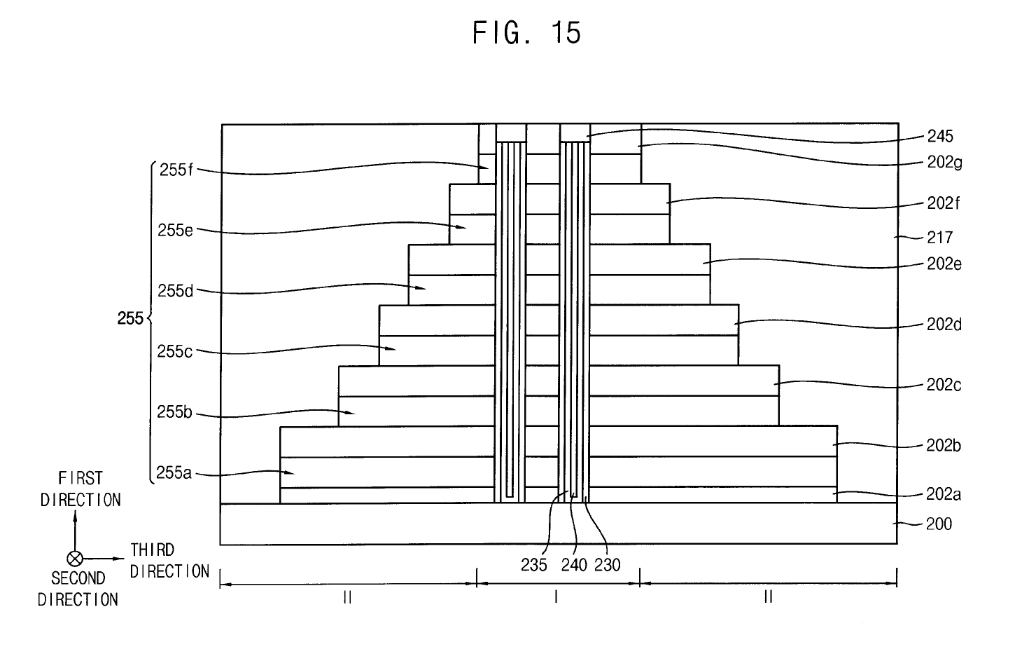

FIGS. 6 to 17 are cross-sectional views and top plan views illustrating a method of manufacturing a semiconductor device in accordance with example embodiments. Specifically, FIGS. 6 to 11, FIG. 13 and FIGS. 15 to 17 are cross-sectional views illustrating the method of manufacturing the semiconductor device. FIGS. 12 and 14 are top plan views illustrating the method of manufacturing the semiconductor device.

For example, FIGS. 6 to 17 illustrate a method of manufacturing a vertical memory device including a vertical channel with respect to a substrate.

In manufacturing the vertical memory device, the method for removing a photoresist illustrated with reference to FIG. 5 may be implemented. In the method of removing a photoresist, the system for removing a photoresist illustrated with reference to FIGS. 1 to 4 may be utilized.

In FIGS. 6 to 17, a direction substantially vertical to a top surface of the substrate is referred to as a first direction, and two directions substantially parallel to the top surface of the substrate and crossing each other are referred to as a second direction and a third direction. For example, the second and third directions may be perpendicular to each other. Additionally, a direction indicated by an arrow in the figures and a reverse direction thereof are considered as the same direction.

Referring to FIG. 6, an insulating interlayer 202 and a sacrificial layer 204 may be alternately and repeatedly formed on the substrate 200 to form a mold structure 210. For example, a plurality of the insulating interlayers 202 (e.g., 202a through 202g) and a plurality of the sacrificial layers 204 (e.g., 204a through 2040 may be alternately formed on each other at a plurality of levels.

The substrate 200 may include a semiconductor material (e.g., single crystalline silicon or single crystalline germanium).

In example embodiments, the insulating interlayer 202 may be formed using an oxide based material, e.g., silicon dioxide, silicon oxycarbide and/or silicon oxyfluoride. The sacrificial layer 204 may be formed using a material that may have an etching selectivity with respect to the insulating interlayer 202 and may be easily removed by a wet etching process. For example, the sacrificial layer 204 may be formed using a nitride based material, e.g., silicon nitride and/or silicon boronitride.

The insulating interlayer 202 and the sacrificial layer 204 may be formed by a chemical vapor deposition (CVD) process, a plasma enhanced chemical vapor deposition (PECVD) process, an atomic layer deposition (ALD) process, and/or a spin coating process. A lowermost insulating interlayer 202a may be formed by a thermal oxidation process on the top surface of the substrate 200. In example embodiments, the lowermost insulating interlayer 202a may have a thin thickness relatively to other insulating interlayers 202b through 202g.

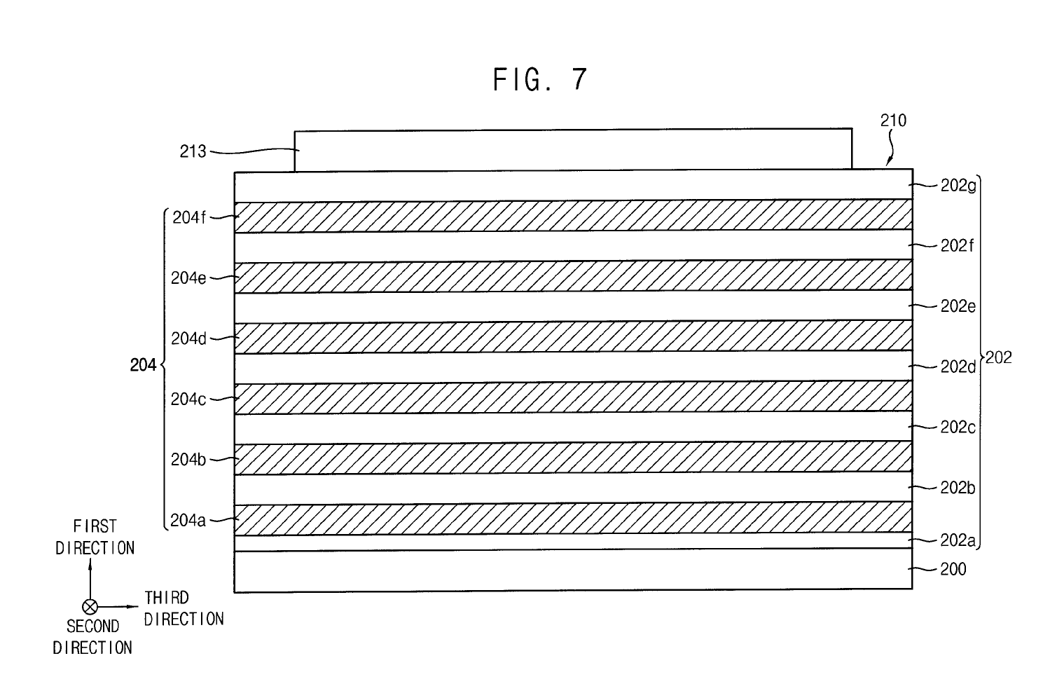

Referring to FIG. 7, a first photoresist pattern 213 may be formed on an uppermost insulating interlayer 202g.

In example embodiments, a photoresist layer may be formed on the uppermost insulating interlayer 202g using a photosensitive material (e.g., a novolac resin). Both ends of the photoresist layer may be removed by exposure and developing processes to form the first photoresist pattern 213. In example embodiments, impurities may be doped with the photoresist layer, and the photoresist layer may have a sufficiently large thickness so that a loss of the first photoresist pattern 213 may be reduced during an etching process for a formation of a stepped mold structure 215 described below

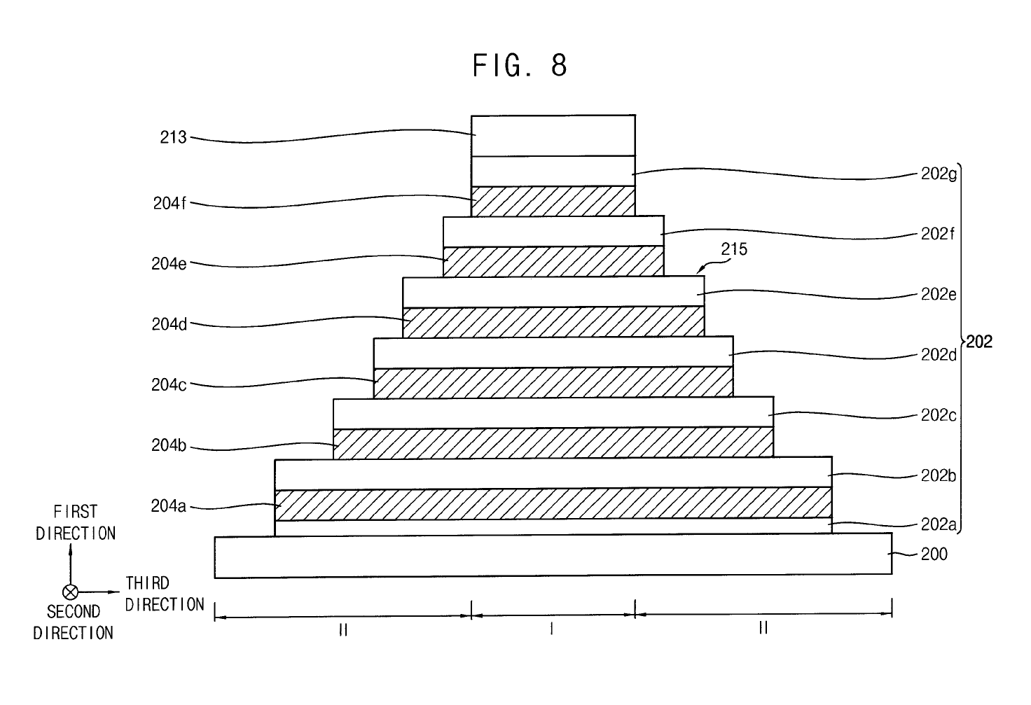

Referring to FIG. 8, lateral portions of the mold structure 210 may be partially etched to form the stepped mold structure 215.

In example embodiments, both ends of the insulating interlayers 202 (e.g., 202g through 202a) and the sacrificial layers 204 (e.g., 204f through 204a) may be etched using the first photoresist pattern 213 as an etching mask. The top surface of the substrate 200 may be exposed because the lowermost insulating interlayer 202a may be partially removed.

Both ends of the first photoresist pattern 213 may then be removed so that a width thereof may be reduced. Next, both ends of the insulating interlayers 202g through 202c and the sacrificial layers 204f through 204b may be etched using the first photoresist pattern 213 as the etching mask again. Subsequently, the width of the first photoresist pattern 213 may be reduced again, and both ends of the insulating interlayers 202g through 202d and the sacrificial layers 204f through 204c may be etched using the first photoresist pattern 213 as the etching mask again. Etching processes may be repeated in a similar manner as described above to obtain the stepped mold structure 215 illustrated in FIG. 8.

The etching processes as described above may be repeated, and thus the first photoresist pattern 213 remaining after the etching processes may have reduced width and thickness relatively to the initially formed first photoresist pattern 213.

The substrate 200 may be divided into a cell region I and an extension region II after the formation of the stepped mold structure 215. The cell region I may be defined as a region substantially overlapping the uppermost insulating interlayer 202g. The extension region II may be defined at both lateral regions of the cell region I. A step or a stair at each level may protrude in the third direction on the extension region II.

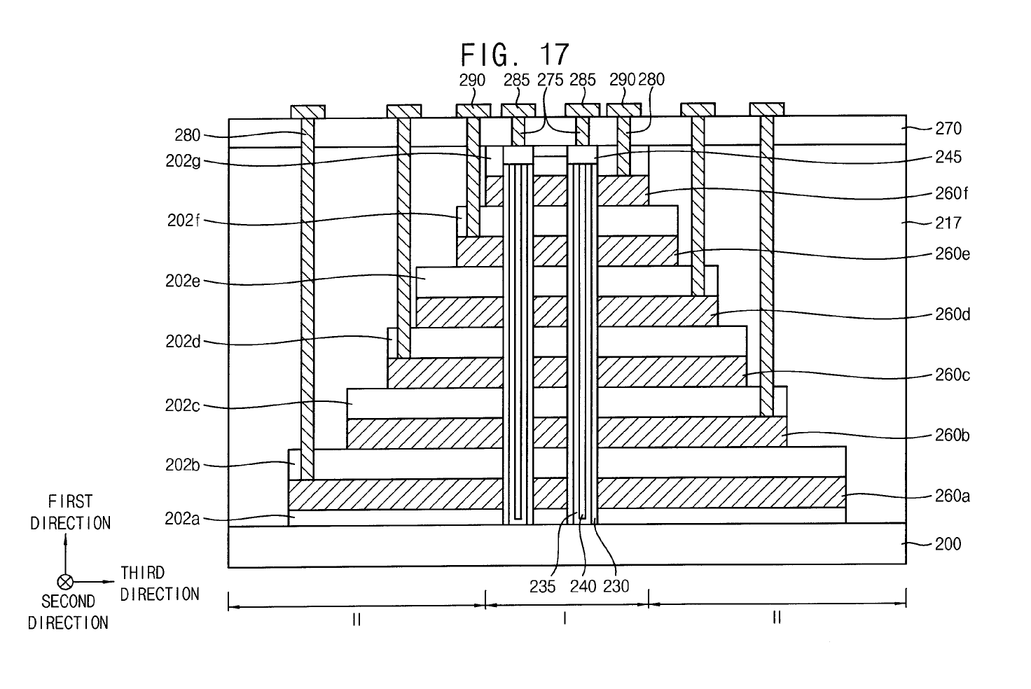

Channels 235 (see FIG. 13) may be formed on the cell region I by a subsequent process to form a cell string. Wiring contacts 280 and wirings 290 (see FIG. 17) may be formed on the extension region II.

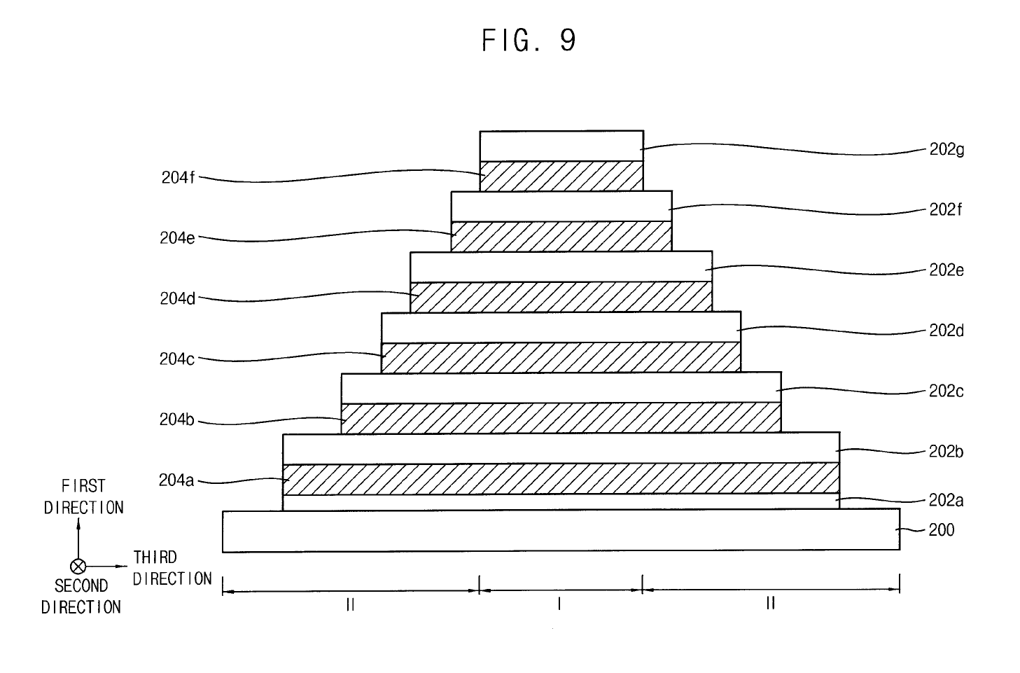

Referring to FIG. 9, the first photoresist pattern 213 may be removed.

In example embodiments, the first photoresist pattern 213 may be removed by the method as illustrated with reference to FIG. 5 using the system illustrated with reference to FIGS. 1 to 4.

For example, a preliminary photoresist removal solution containing a peroxide (e.g., hydrogen peroxide) may be activated in the solution activation unit 120 of FIG. 1. The substrate 200 on which the stepped mold structure 215 and the first photoresist pattern 213 are formed may be loaded in the photoresist removal unit 170. An activated photoresist removal solution may be provided on the substrate 200 from the solution activation unit 120 to remove the first photoresist pattern 213.

As described above, the preliminary photoresist removal solution and the activated photoresist removal solution may not include an acid ingredient (e.g., phosphoric acid, sulfuric acid, nitric acid or fluoric acid), so that the first photoresist pattern 213 may be selectively removed without damaging the insulating interlayer 202 and the sacrificial layer 204.

In example embodiments, an ashing process may be performed on the substrate 200 before providing the activated photoresist removal solution.

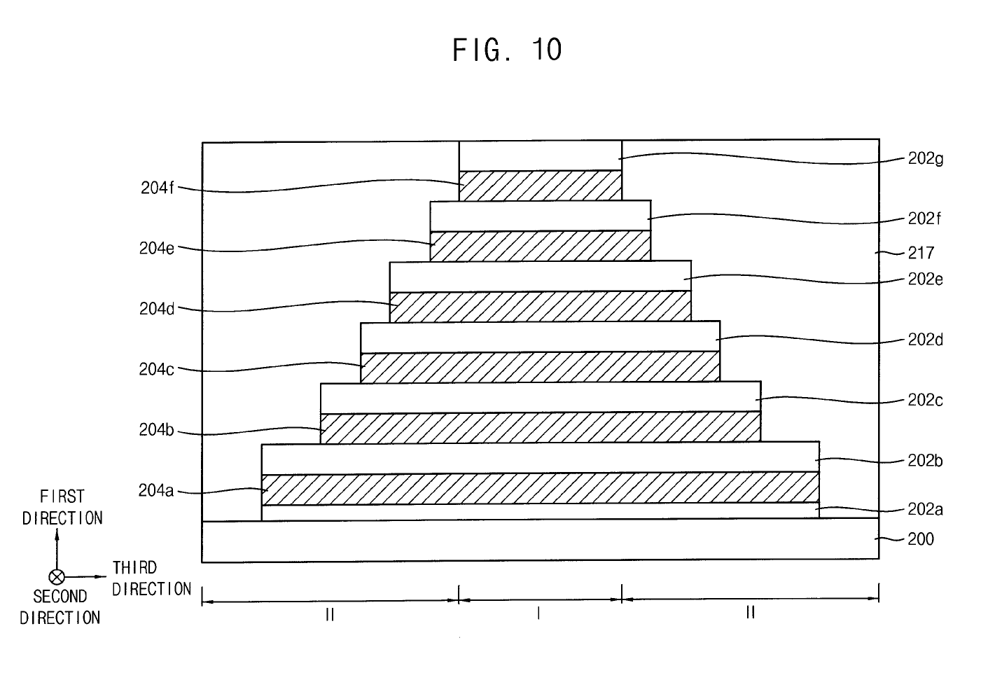

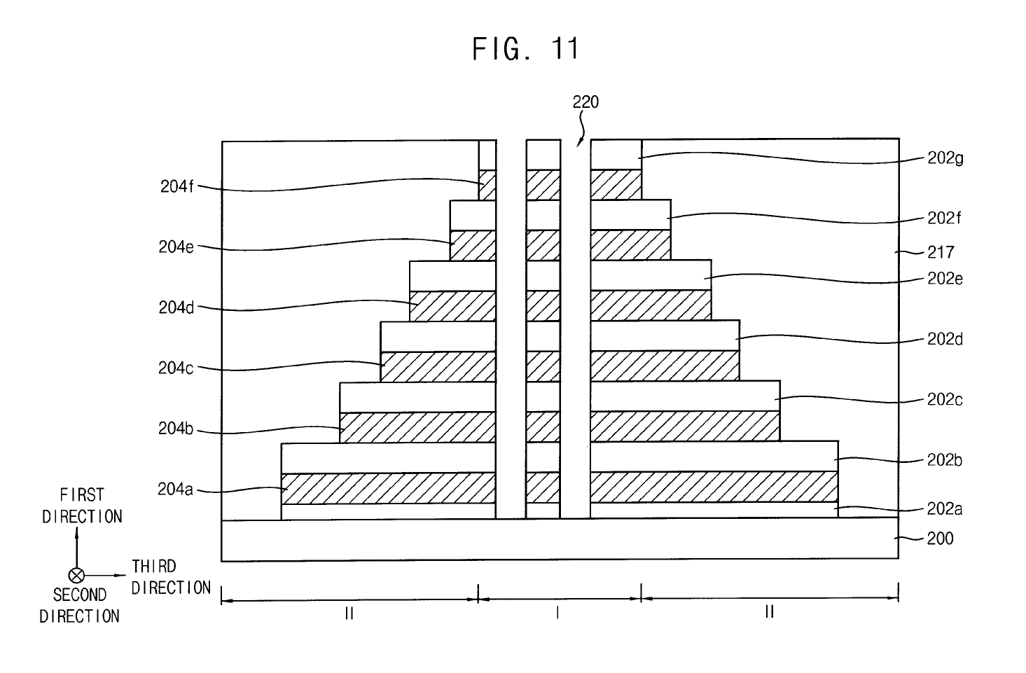

Referring to FIG. 10, a mold protection layer 217 covering lateral portions or steps of the stepped mold structure 215 may be formed.

For example, an insulation layer covering the stepped mold structure 215 may be formed on the substrate 200 using, e.g., silicon oxide by a CVD process or a spin coating process. An upper portion of the insulation layer may be planarized until the uppermost insulating interlayer 202g is exposed to form the mold protection layer 217. The planarization process may include a chemical mechanical polish (CMP) process and/or an etch-back process.

Referring to FIG. 11 and FIG. 12 that is a top plan view of FIG. 11, channel holes 220 may be formed through the stepped mold structure 215. The top surface of the substrate 200 may be exposed through the channel holes 220.

For example, a hard mask (not illustrated) may be formed on the uppermost insulating interlayer 202g and the mold protection layer 217. The insulating interlayers 202 and the sacrificial layers 204 of the stepped mold structure 215 may be partially etched by performing, e.g., a dry etching process using the hard mask as an etching mask to form the channel holes 220.

The hard mask may be formed using a material that may have an etching selectivity with respect to the insulating interlayer 202 and the sacrificial layer 204. For example, the hard mask may be formed using polysilicon or amorphous silicon. In example embodiments, the hard mask may be formed of silicon-based or carbon-based spin-on hardmask (SOH) materials. The hard mask may be removed by an ashing process and/or a strip process after the formation of the channel holes 220.

In example embodiments, the hard mask may be formed using a photoresist material. In example embodiments, the hard mask may be removed by the method illustrated with reference to FIG. 5.

In example embodiments, a plurality of the channel holes 220 may be formed in the third direction to form a channel hole row. A plurality of the channel hole rows may be formed in the second direction to form a channel hole array.

FIGS. 11 and 12 illustrate that each of the channel hole rows includes two channel holes 220, however, at least three channel holes 220 may be included in the each of the channel hole rows.

Referring to FIG. 13, a dielectric layer structure 230, a channel 235 and a first filling layer pattern 240 may be formed in the channel hole 220, and a pad 245 capping an upper portion of the channel hole 220 may be formed on the dielectric layer structure 230, the channel 235 and the first filling layer pattern 240.

In example embodiments, the dielectric layer structure 230 may be formed on a sidewall of the channel hole 220. The dielectric layer structure 230 may include a blocking layer, a charge storage layer and a tunnel insulation layer sequentially stacked from the sidewall of the channel hole 220. For example, the dielectric layer structure 230 may be formed as an oxide-nitride-oxide (ONO) layer structure. The dielectric layer structure 230 may have a substantially hollow cylindrical shape or a substantially straw shape.

A channel layer may be formed along the uppermost insulating interlayer 202g, the mold protection layer 217, a sidewall of the dielectric layer structure 240 and the top surface of the substrate 200 exposed through the channel hole 220. A first filling layer filling a remaining portion of the channel hole 220 may be formed on the channel layer. Upper portions of the first filling layer and the channel layer may be planarized until top surfaces of the insulating interlayer 202g and/or the mold protection layer 217 are exposed to form the channel 235 and the first filling layer pattern 240.

The channel 235 may have a substantially cup shape. The first filling layer pattern 240 may have a substantially pillar shape or a substantially solid cylindrical shape. In example embodiments, the channel layer may sufficiently fill the channel hole 220. In example embodiments, the formation of the first filling layer pattern 240 may be omitted.

For example, upper portions of the dielectric layer structure 230, the channel 235 and the first filling layer pattern 240 may be removed by an etch-back process to form a recess. A pad layer filling the recess may be formed on the uppermost insulating interlayer 202g and the mold protection layer 217. An upper portion of the pad layer may be planarized to form the pad 245.

The channel layer and the pad layer may be formed using polysilicon optionally doped with impurities. In example embodiments, a crystallization process including a thermal treatment or a laser beam irradiation may be further performed after forming the channel layer and/or the pad layer. The first filling layer may be formed of, e.g., silicon oxide.

A plurality of the channels 235 and the pads 245 may be arranged along the second and third directions to form a channel array and a pad array comparable to the channel hole array. The channel array and the pad array may include channel rows and pad rows, respectively, arranged along the second direction.

Referring to FIG. 14, portions of the stepped mold structure 215 and the mold protection layer 217 between some of the channel rows neighboring each other may be etched to form an opening 250.

In example embodiments, a second photoresist pattern (not illustrated) covering the pads 245 may be formed on the uppermost insulating interlayer 202g and the mold protection layer 217. The mold protection layer 217, the insulating interlayers 202 and the sacrificial layers 204 may be partially etched using the second photoresist pattern as an etching mask to form the opening 250.

The opening 250 may extend linearly in the third direction, and a plurality of the openings 250 may be formed along the second direction. The top surface of the substrate 200 may be exposed through the opening 250, and the insulating interlayers 202 and the sacrificial layers 204 may be exposed by a sidewall of the opening 250.

In example embodiments, the second photoresist pattern may be removed by the method illustrated with reference to FIG. 5 after the formation of the opening 250. For example, a preliminary photoresist removal solution consisting essentially of hydrogen peroxide may be activated through, e.g., a UV irradiation to produce an activated photoresist removal solution. The activated photoresist removal solution may be provided on the substrate 200 to remove the second photoresist pattern.

As described above, the preliminary photoresist removal solution and the activated photoresist removal solution may not include an acid ingredient, so that the insulating interlayer 202, the sacrificial layer 204 and the mold protection layer 217 including an oxide or a nitride may not be removed or damaged.

Additionally, the preliminary photoresist removal solution may be sufficiently activated prior to being provided on the substrate, so that hydrogen peroxide included in the preliminary photoresist removal solution may be fully converted into a hydroxyl radical. Accordingly, the pad 245 and/or the channel 235 may be prevented or inhibited from being damaged by hydrogen peroxide.

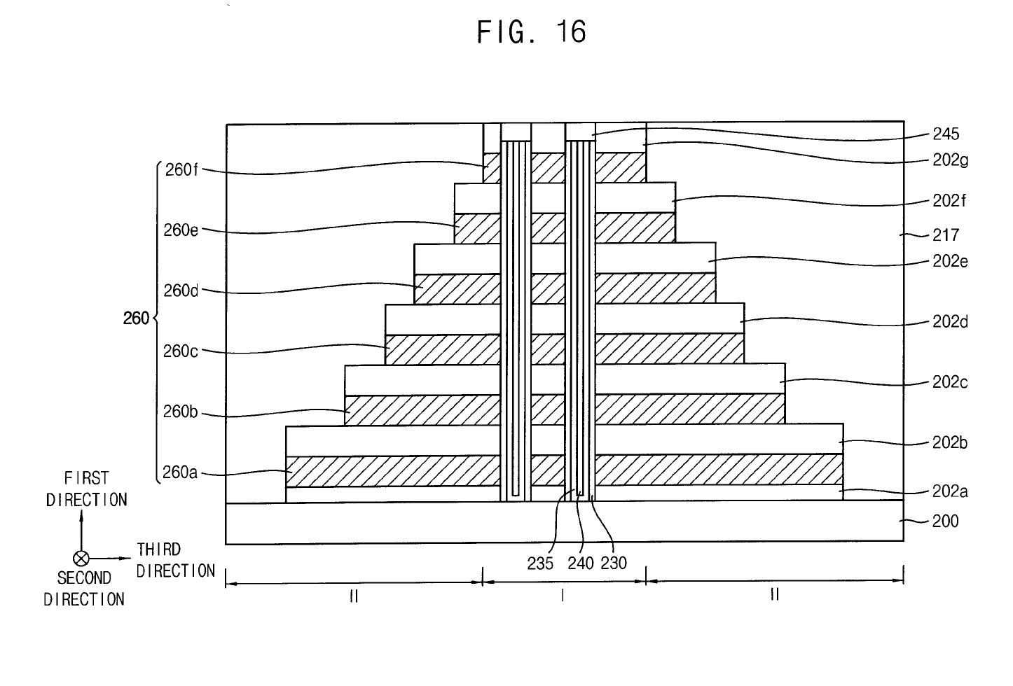

Referring to FIG. 15, the sacrificial layers 204 exposed by the opening 250 may be removed.

In example embodiments, the sacrificial layers 204 may be selectively removed by a wet etching process in which an etchant solution including phosphoric acid or sulfuric acid may be used. Gaps 255 (e.g., 255a through 255f) may be formed at spaces from which the sacrificial layers 204 are removed. An outer sidewall of the dielectric layer structure may be exposed by the gaps 255.

Referring to FIG. 16, a gate line 260 may be formed in the gap 255 of each level.

In example embodiments, a gate electrode layer may be formed on inner walls of the gaps 255, the outer sidewall of the dielectric layer structure 230 and surfaces of the insulating interlayers 202. The gate electrode layer may fill the gaps 255 and may partially fill the opening 250. The gate electrode layer may be formed using a conductive material, for example, a metal or a metal nitride by, e.g., an ALD process, a CVD process or a sputtering process.

Subsequently, a portion of the gate electrode layer formed in the opening 250 may be etched to form the gate line 260.

In example embodiments, a lowermost gate line 260a may serve as a ground selection line (GSL). Four gate lines 260b, 260c, 260d and 260e may serves as word lines. An uppermost gate line 260f on the word lines may serve as a string selection line (SSL). FIG. 15 illustrates that the GSL, the word lines and the SSL are formed at a single level, 4 levels and a single level, respectively. However, the levels of the GSL, the word line and the SSL are not specifically limited herein. For example, each of the GSL and the SSL may be formed at 2 levels, and the word lines may be formed at more than 4 levels, e.g., 6 levels, 8 levels, or 12 levels.

Referring to FIG. 17, an upper insulation layer 270 may be formed on the uppermost insulating interlayer 202g, the mold protection layer 217 and the pads 245. The upper insulation layer 270 may be formed of silicon oxide by, e.g., a CVD process or a spin coating process.

In example embodiments, the upper insulation layer 270 may sufficiently fill the opening 250 to cover the insulating interlayer 202g and the mold protection layer 217. In example embodiments, before the formation of the upper insulation layer 270, n-type impurities may be implanted through the opening 250 to form an impurity region at an upper portion of the substrate 200. The impurity region may serve as a common source line (CSL).

A bit line contact 275 may be formed on the cell region I to extend through the upper insulation layer 270 and contact the pad 245. A gate line contact 280 may be formed through the upper insulation layer 270, the mold protection layer 217 and the insulating interlayer 202 to be in contact with the gate line 260 of each level.

In example embodiments, the gate line contacts 280 may be formed alternately on the both extension regions II. For example, the gate line contacts 280 may be formed in a zigzag arrangement along the first direction. The gate line contacts 280 may be dispersed in the both extension region II, so that a process tolerance for wirings and/or contacts may be additionally achieved.

A bit line 285 and a wiring 290 electrically connected to the bit line contact 275 and the gate line contact 280, respectively, may be formed on the upper insulation layer 270.

As illustrated in FIG. 17, the bit line 285 and the wiring 290 may extend in substantially the same direction, e.g., the second direction. However, the bit line 285 and the wiring 290 may extend in different directions depending on a circuit design.

As illustrated in FIG. 17, the bit line 285 and the wiring 290 may be formed at substantially the same level or on substantially the same layer. However, the bit line 285 and the wiring 290 may be formed at different levels or on different layers. For example, the wiring 290 may be formed on the mold protection layer 217, and the bit line 285 may be formed on the upper insulation layer 270.

The bit line contact 275, the gate line contact 280, the bit line 285 and the wiring 290 may be formed of a metal or a metal nitride by, e.g., an ALD process, a PVD process or a sputtering process.

According to example embodiments of the present inventive concepts, a preliminary photoresist removal solution including a peroxide may be pre-activated through, e.g., a UV irradiation. The preliminary photoresist removal solution may be converted into an activated photoresist removal solution including an active species, e.g., a hydroxyl radical. The activated photoresist removal solution may be applied to a substrate on which a photoresist pattern is formed to remove the photoresist pattern. The photoresist removal solution may be activated prior to being provided on the substrate, so that a process time and an amount of a photoresist residue may be reduced. Additionally, the photoresist removal solution may not include an acid ingredient so that an environmental pollution and damages of other structures may be avoided.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concepts. Accordingly, all such modifications are intended to be included within the scope of the present inventive concepts as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A system for removing a photoresist, comprising:
a solution storage configured to store a preliminary photoresist removal solution;
a solution activation unit configured to convert the preliminary photoresist removal solution from the solution storage into an activated photoresist removal solution; and
a photoresist removal unit configured to receive the activated photoresist removal solution from the solution activation unit, and configured to load a substrate including a photoresist pattern formed thereon.

2. The system of claim 1, wherein the solution activation unit includes:
a reactor configured to receive the preliminary photoresist removal solution; and
at least one energy supplier configured to irradiate an activation energy onto the reactor.

3. The system of claim 2, wherein the at least one energy supplier includes an ultraviolet lamp.

4. The system of claim 2, wherein
the at least one energy supplier is a plurality of the energy suppliers arranged in parallel in the solution activation unit, and
the reactor includes a plurality of activation flow paths between the plurality of energy suppliers.

5. The system of claim 2, wherein
the at least one energy supplier is a plurality of the energy suppliers arranged in parallel in the solution activation unit, and
the reactor includes an activation flow path extending between the plurality of energy suppliers in a continuous zigzag structure.

6. The system of claim 2, further comprising:
a first flow path between the reactor and the solution storage;
a second flow path between the reactor and the photoresist removal unit; a first mass flow controller in the first flow path; and
a second mass flow controller in the second flow path.

7. The system of claim 6, further comprising:
an activation monitoring device coupled to the reactor for measuring a degree of activation in the activated photoresist removal solution.

8. The system of claim 7, wherein the second mass flow controller is opened when a target value of the degree of activation is measured by the activation monitoring device.

9. The system of claim 1, wherein the photoresist removal unit includes:
a supporter on which the substrate is loaded; and
a removal solution supplier on the supporter, the removal solution supplier configured to provide the activated photoresist removal solution onto the substrate.

10. A method of removing a photoresist, comprising:
preparing a preliminary photoresist removal solution including a peroxide;
activating the preliminary photoresist removal solution to produce an activated photoresist removal solution;
loading a substrate on which a photoresist pattern is formed in a process chamber; and
providing the activated photoresist removal solution into the process chamber.

11. The method of claim 10, wherein the preparing prepares the peroxide consisting essentially of hydrogen peroxide.

12. The method of claim 11, wherein the activating activates the preliminary photoresist removal solution to produce the activated photoresist removal solution including a hydroxyl radical generated from the peroxide.

13. The method of claim 10, wherein the preparing prepares the preliminary photoresist removal solution excluding an acid ingredient.

14. The method of claim 10, wherein the activating irradiates an ultraviolet light onto the preliminary photoresist removal solution.

15. The method of claim 10, further comprising:
measuring an absorbance of one of the preliminary photoresist removal solution and the activated photoresist removal solution in real-time.

16. A system for removing a photoresist, comprising:
a first unit configured to store a photoresist removal solution, the photoresist removal solution including a peroxide;
a second unit configured to expose the photoresist removal solution; and
a third unit configured to apply the exposed photoresist removal solution to a photoresist pattern.

17. The system of claim 16, wherein the second unit exposes the photoresist removal solution using UV irradiation.

18. The system of claim 16, wherein the photoresist removal solution excludes an acid.

19. The system of claim 16, wherein the exposed photoresist removal solution includes a hydroxide radical generated from the peroxide.

20. The system of claim 16, wherein the peroxide consists essentially of hydrogen peroxide.
